(19) United States
(12) Patent Application Publication
(10) Pub. No.: US 2026/0182380 A1
(43) Pub. Date: Jun. 25, 2026

(54) SUBSTRATE SURFACE TREATMENT FOR STIFFENER BONDING

(71) Applicant: Intel Corporation, Santa Clara, CA (US)

(72) Inventor: Thien Bao HOANG, Ho Chi Minh City (VN)

(21) Appl. No.: 19/001,122

(22) Filed: Dec. 24, 2024

(51) Int. Cl. H01L 23/00; H01L 21/02; H01L 25/065

(52) U.S. Cl. CPC H10W 42/121; H10P 14/6506; H10P 14/6548; H10W 90/00

(57) ABSTRACT

A device package and a method of forming a device package are described. The device package includes a substrate and a stiffener. A portion of a top surface of the substrate is treated prior to stiffener attachment to change a profile of the portion. An adhesive material applied between a bottom surface of the stiffener and the treated substrate creates a more durable bond when attaching the stiffener to the substrate. An in-line process to treat the substrate to change the profile includes marking the portion of the top surface with a pattern and/or a barrier that creates a texture that improves surface wettability and effectiveness of adhesive material filling, and reduces defects in the device package, including stiffener delamination.

### FIELD

Embodiments relate to semiconductor devices. More particularly, the embodiments relate to manufacturing semiconductor device packages with stiffener attachments using a substrate surface treatment for enhanced stiffener bonding to a substrate to reduce defects.

### BACKGROUND

Semiconductor device packages (referred to herein as devices or device packages) are often manufactured with stiffeners attached to the semiconductor substrate to increase the durability of the product. In a high volume semiconductor device manufacturing environment, devices with stiffener attached to the semiconductor substrate can encounter defects that impact device quality. For example, stiffener delamination can be especially common with certain stiffener shapes, such as curved, or U-shaped, stiffeners. Among other issues, stiffener delamination is associated with solder mask tearing, which can cause broken copper (Cu) trace interconnects.

### BRIEF DESCRIPTION OF THE DRAWINGS

The following description includes discussion of figures having illustrations given by way of example of implementations of embodiments of the invention. The drawings should be understood by way of example, and not by way of limitation. As used herein, references to one or more “embodiments” are to be understood as describing at least one implementation of the invention that includes one or more particular features, structures, or characteristics. Thus, phrases such as “in one embodiment” or “in an alternate embodiment” appearing herein describe various embodiments and implementations of the invention, and do not necessarily all refer to the same embodiment. However, they are also not necessarily mutually exclusive.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

It is noted that the views, block diagrams and the like in the drawings are illustrative and not drawn to scale. For example, the relative dimensions and placements for some of the components in the views and block diagrams herein are exaggerated for clarity and point of illustration. For example, one having skill in the art will recognize the components in an actual implementation will generally have dimensions and thicknesses that are different than that shown in the Figures herein (e.g., substantially smaller and/or thinner), or be placed in a manner that is different from what is represented in a block diagram or other illustration.

FIG. 1A is a plan (top) view of a device package having a stiffener and one or more dies attached to the substrate, according to one embodiment;

FIG. 1B is a cross-sectional view of the device package of FIG. 1A (omitting the dies) illustrating the stiffener, adhesive fill, solder mask, the substrate, and an adhesive fill defect, according to one embodiment;

FIG. 1C is another cross-sectional view of the device package of FIG. 1A (omitting the dies) illustrating the stiffener, adhesive fill, solder mask, the substrate, and a stiffener delamination defect, according to one embodiment;

FIG. 2A is a plan (top) view of the device package of FIG. 1A having the stiffener and one or more one or more dies attached to the substrate, and an identification of two parts of the stiffener that are prone to failure when attaching the stiffener to the surface of the substrate, according to one embodiment;

FIG. 2B is a perspective view of the substrate of the device package of FIG. 2A (omitting the dies), the stiffener, the substrate surface, the stiffener area of the substrate surface, “keep-in-zone” (KIZ) portions of the stiffener area of the substrate surface and a marker tool, according to one embodiment;

FIGS. 3A-3B are flow diagrams illustrating example processes for implementing a substrate surface treatment for stiffener bonding, in accordance with embodiments described herein;

FIGS. 4A-4B depicts example surface textures and shapes that can be marked on the substrate surface as a substrate surface treatment for stiffener bonding, in accordance with embodiments described herein;

FIG. 5 is a schematic block diagram illustrating a computer system that utilizes a device package having a stiffener attached to the substrate surface using a substrate surface treatment for stiffener bonding, in accordance with embodiments described herein.

### DETAILED DESCRIPTION

Stiffener delamination in a semiconductor device package occurs after the stiffener is bonded to the substrate surface as well as after the chip assembly and test processes. Root causes can include insufficient liquid electrically conductive adhesive (ECA) material (used as the bonding adhesive) between the stiffener and the substrate surface. Another cause is insufficient flow of the ECA material such that it cannot reach attachment areas of the substrate surface underneath the stiffener. Contamination on the substrate surface can also prevent the ECA material flow effectiveness during bonding. Current methods of stiffener bonding rely on adhesive bonding from ECA material disposed between the bottom surface of the stiffener and the solder resist mask. Current processes for stiffener bonding use parameters such as the ECA dot weight, thermal application and bonding force to affect the bonding result. In contrast, the substrate surface has not previously been a consideration for improving stiffener bonding.

Insufficient ECA material and insufficient flow of the ECA material to the attachment areas of the substrate surface can weaken the bonding between the stiffener and the solder resist mask, thus causing a defect such as delamination. Improvements in the current process are difficult to make and control. For example, simply adding more ECA material to improve filling effectiveness can lead to another failure mode due to excess ECA filling.

Moreover, delamination of the stiffener cannot be detected by a post-stiffener attachment in-line inspection, or by a finished goods inspection. Currently, the only way that defects causing stiffener delamination can be revealed is when the defect triggers unit warpage data indicating warping and abnormal behavior. Altogether, delamination of the stiffener presents as a high-risk defect that is difficult to contain with current in-line detection.

To address this challenge, a new process feature is disclosed that enables current marking equipment, such as laser tray in-line marking equipment or other types of marking equipment, to treat the substrate surface prior to attachment of the stiffener to improve surface wettability and effectiveness of ECA material filling.

In one embodiment, the new process feature, referred to herein as a substrate surface treatment for stiffener bonding, treats the substrate surface underneath the stiffener, referred to as the stiffener area of the substrate surface, prior to attachment. Treating the substrate surface not only cleans the stiffener area of the substrate surface, but also increases the wettability and roughness, thereby improving adhesive bonding between the bottom surface of the stiffener, and the stiffener area of the substrate surface / solder mask. In a typical embodiment, the surface treatment for stiffener bonding is performed in-line, as part of the overall device package / chip assembly process flow.

To minimize the cost of a substrate surface treatment for stiffener bonding, in one embodiment, the treatment is limited to one or more portions of the stiffener area of the substrate surface underneath corresponding parts of the stiffener that are prone to failure, such as stiffener delamination. The one or more portions are referred to herein as “keep-in-zone” portions (“KIZ” portions) of the stiffener area. Limiting the treatment of the substrate surface to the KIZ portions of the stiffener area reduces the cost and overhead associated with the new process feature.

In one embodiment, the treatment includes texturing of the stiffener area of the substrate surface (or just the KIZ portions), and can include marking a barrier around the perimeter of the stiffener area (or just the KIZ portions) to act as a glue barrier to improve other failure modes, such as leakage of the ECA material onto undesired locations of the solder mask and/or substrate surface.

In one embodiment, the marking equipment used to treat the stiffener area of the substrate surface includes existing in-line ATM Laser Tray Markers, currently used for content marking, adapted to texturize, and/or mark a barrier around the perimeter of, the stiffener area of the substrate surface (or just the KIZ portions). In this manner, the new process feature of substrate surface treatment for stiffener bonding is backward-compatible with legacy marker tools. In addition, in other embodiments, newer generations of marking equipment can be used to treat the substrate surface.

In one embodiment, the surface treatment for stiffener bonding is integrated with current in-line substrate process flows, e.g., device package and chip assembly, prior to attachment of the stiffener.

In the detailed description that follows are processes for forming semiconductor devices (or device packages) with stiffeners attached to a substrate surface using adhesive material in accordance with embodiments for substrate surface treatment for stiffener bonding. Specifically, the device packages described herein include treated substrate surfaces for enhancing stiffener bonding between the stiffener and the substrate to minimize defects, including defects such as delamination of the stiffener after attachment. The present embodiments further enhance packaging solutions by enabling a cost-efficient solution that uses marking tools to minimize the occurrence of defects arising from faulty stiffener attachment in device packages.

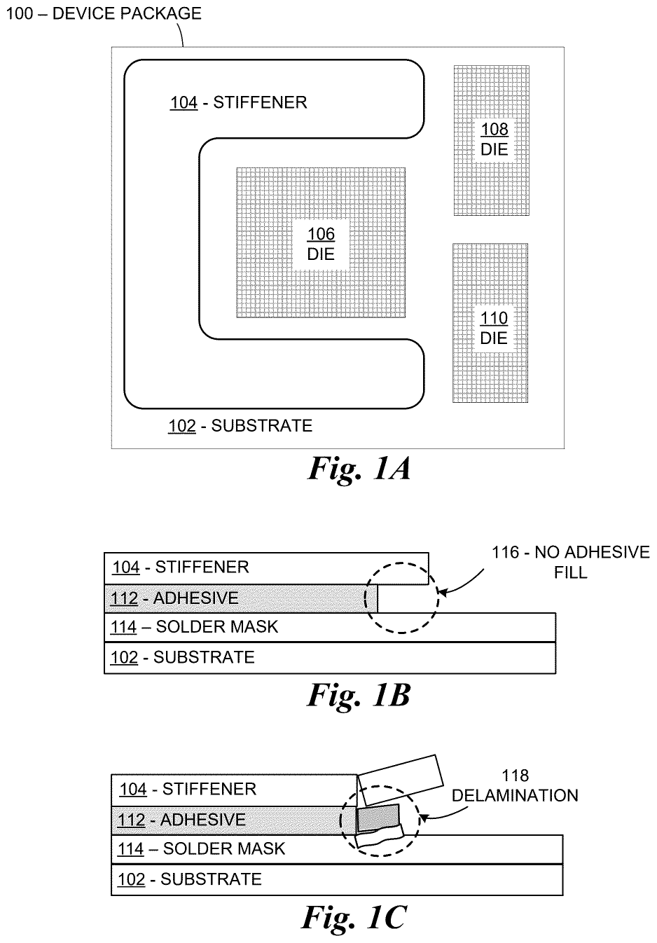

FIG. 1A is a plan (top) view of a device package 100 having packaging components, such as a stiffener 104 and one or more dies 106, 108 and 110, attached to a top surface of a substrate 102 (omitting the solder mask), according to one embodiment. Note that the device package 100, as shown in FIG. 1A, may include fewer or additional packaging components based on the desired packaging design, such as posts, additional dies, balls and other structures, etc.

According to some embodiments, the substrate 102 may include, but is not limited to, a package, a substrate, and a printed circuit board (PCB). In one embodiment, the substrate 102 is a PCB. For one embodiment, the PCB is made of an FR-4 glass epoxy base with thin copper foil laminated on both sides (not shown). In some embodiments, a multilayer PCB can be used, with pre-preg and copper foil (not shown) used to make additional layers. For example, the multilayer PCB may include one or more dielectric layers, where each dielectric layer can be a photosensitive dielectric layer (not shown). In some embodiments, holes (not shown) may be drilled in substrate 102. In one embodiment, the substrate 102 may also include conductive copper traces, metallic pads, and holes (not shown).

In one embodiment, the stiffener 104 may be a curved shape customized to a particular device package 100. Other shapes, such as angular shapes, and other sizes of stiffeners may be used, including multiple stiffeners for a single device package 100. The bottom of the stiffener 104 is attached to the surface of the substrate 102 to strengthen the device package 100.

FIG. 1B is a cross-sectional view of the device package 100 of FIG. 1A, illustrating the stiffener 104, an adhesive 112 such as an ECA, a solder mask 114, the substrate 102, and an adhesive fill defect 116, according to one embodiment. As shown, the bottom of the stiffener 104 is attached to the top surface of the substrate 102/solder mask 114 using an adhesive filler 112, such as an ECA material. The adhesive fill defect 116 includes an area underneath the stiffener 104 in which no adhesive fill is present. As noted, this can occur for multiple reasons, including inadequate ECA material or ineffective ECA material filling.

FIG. 1C is another cross-sectional view of the device package 100 of FIG. 1A and FIG. 1B, illustrating a stiffener delamination defect 118, according to one embodiment. As shown, a delamination defect 118 typically occurs as a result of a tear in the solder mask 114 at or near the area of the adhesive fill defect 116. The tear in the solder mask 114, the insufficient and/or ineffective adhesive 112, can cause the stiffener 104 to delaminate 118 from the substrate 102 after attachment of the bottom of the stiffener 104 with adhesive 112 to the surface of the substrate 102/solder mask 114.

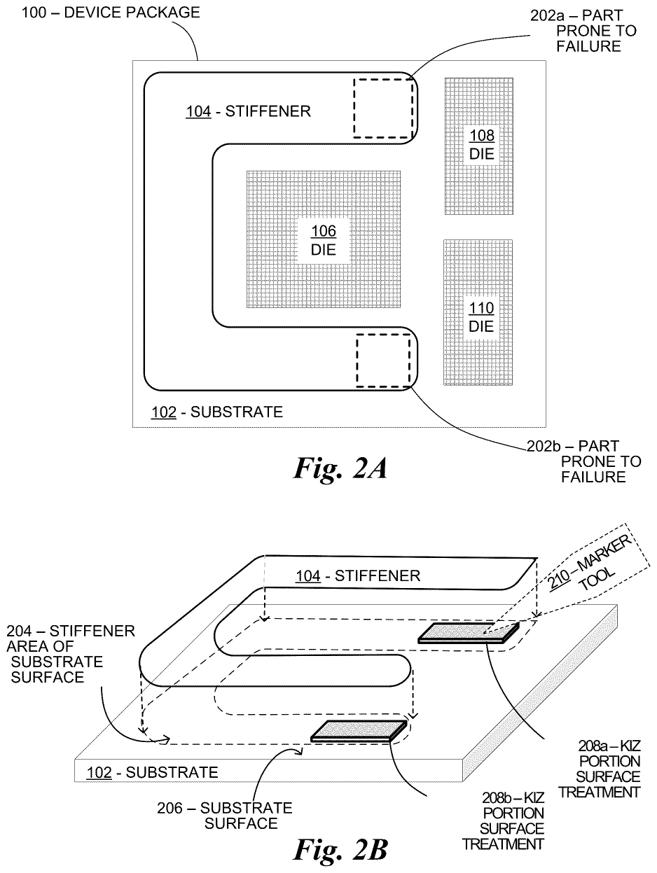

FIG. 2A is a plan (top) view of the device package 100 of FIG. 1A having the stiffener 104 and one or more one or more dies 106, 108 and 110 attached to the substrate 102, according to one embodiment. As shown, portions 202a and 202b of the stiffener 104 have been identified as parts of stiffener 104 prone to failure.

FIG. 2B is a perspective view of the stiffener 104 and the substrate 102 of the device package 100 of FIG. 2A, according to one embodiment. As shown in an exploded view, the stiffener area 204 of the substrate surface 206 of substrate 102 corresponds to the stiffener 104 being attached to the substrate surface 206. Within the stiffener area 204 are two “keep-in-zone” (KIZ) portions, 208a and 208b, marked with a substrate surface treatment to enhance stiffener bonding, according to one embodiment.

The KIZ portions 208a and 208b correspond to the parts 202a and 202b of the stiffener 104 identified as prone to failure in FIG. 2A. In one embodiment, a product assembly drawing will identify the KIZ portions 208a and 208b for use by a marking tool 210. In one embodiment, the corresponding KIZ portions 208a and 208b may or may not conform exactly to the identified parts 202a and 202b prone to failure. The corresponding KIZ portions 208a and 208b are, however, contained within the stiffener area 204 of the substrate surface 206 and may be shaped and treated according to the capabilities of the marker tool 210. In one embodiment, the surface treatment of the KIZ portions 208a and 202b is performed by the marker tool 210 as an in-line substrate surface treatment prior to attachment of the stiffener 104 to the substrate surface 206 to prevent or at least minimize the risk of defects, including subsequent delamination of the stiffener 104.

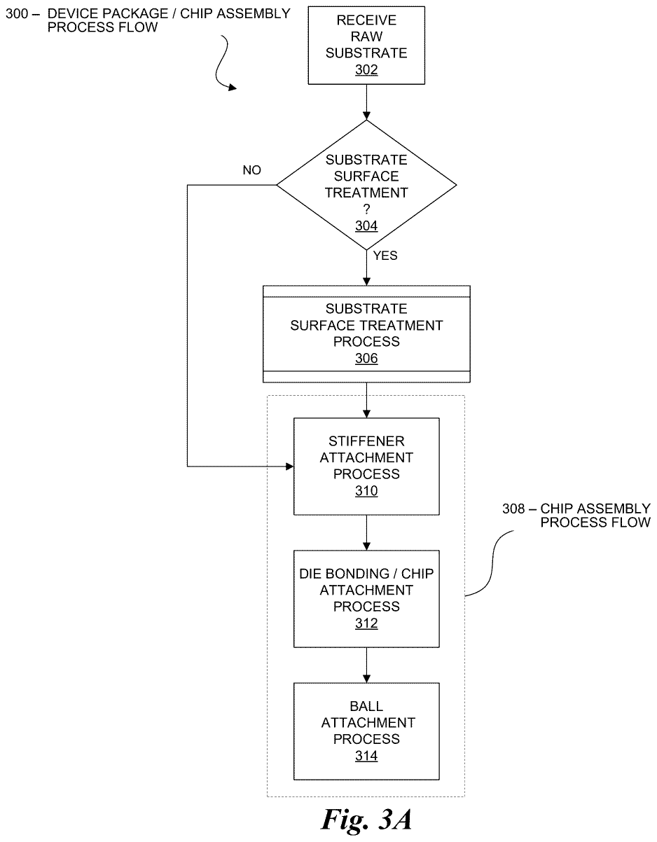

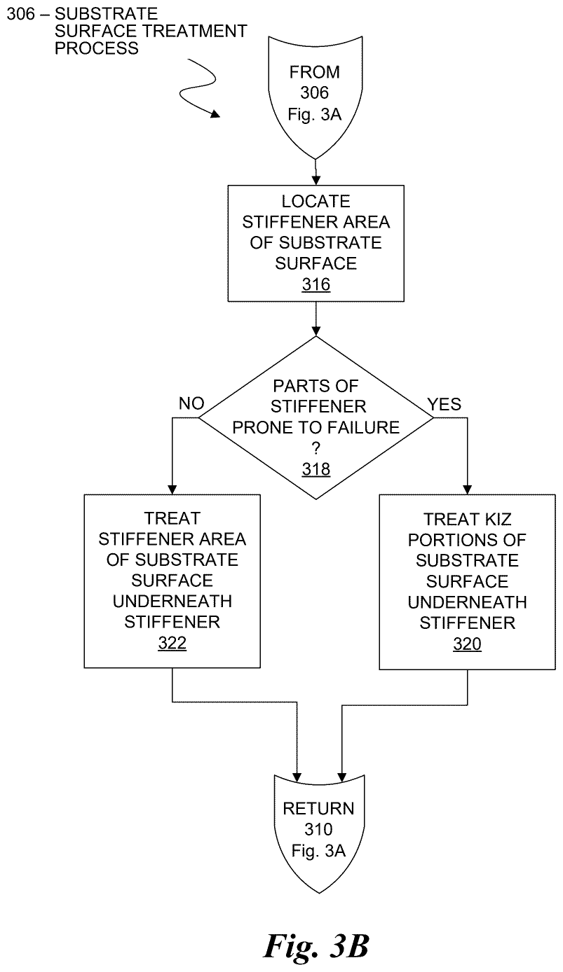

FIGS. 3A-3B are flow diagrams illustrating example processes 300 for implementing a substrate surface treatment for stiffener bonding, in accordance with embodiments described herein. In one embodiment, the surface treatment for stiffener bonding, illustrated in FIG. 3A as substrate surface treatment process 306, is integrated with in-line substrate process flows, e.g., the device package and chip assembly process flows 300 and 308, prior to attachment of the stiffener at process 310. The process 300 begins at 302 with the receipt of a raw substrate material, and the determination at decision block 304 whether a substrate surface treatment 306 is selected for the device package being assembled. If not, the substrate surface treatment process 306 is bypassed and process 300 continues with the chip assembly process flow 308 at the stiffener attachment process 310.

In one embodiment, if the substrate surface treatment 306 is selected for the device package being assembled, then process 306 branches to FIG. 3B, at 316, to locate the stiffener area of the substrate surface to be treated. At decision block 318, the substrate surface treatment process 306 determines whether parts of the stiffener have been identified as prone to failure. If not, then the substrate surface treatment process 306 proceeds at 322 to treat the entire stiffener area of the substrate surface underneath the stiffener. In a typical embodiment, however, parts of the stiffener will have been identified as prone to failure, and the substrate surface treatment process 306 instead proceeds at 320 to treat only the KIZ portions of the substrate surface underneath the stiffener that correspond to the parts of the stiffener that have been identified as prone to failure. The substrate surface treatment process 306 concludes with the return to FIG. 3A, at 310, to resume the chip assembly process flow 308, including the stiffener attachment process 310, followed by the die bonding/chip attachment process 312 and the ball attachment process 314, and any other processes (not shown) for completion of the device package.

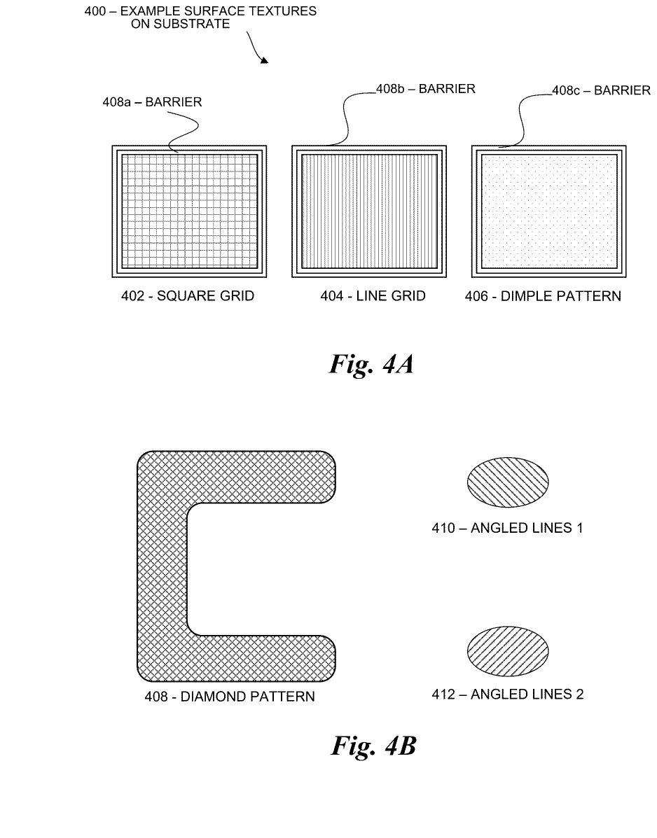

FIGS. 4A-4B depicts example surface textures and shapes that can be marked on the substrate surface as a substrate surface treatment for stiffener bonding, in accordance with embodiments described herein. In one embodiment, all or a portion of the stiffener area of the substrate surface is treated with a texturing, such as patterns 402 square grid, 404 line grid and 406 dimple pattern and/or a barrier, 408a, 408b, 408c. In a typical embodiment, the treated area will include two parts: the texturing pattern, 402, 404, 406 and the barrier 408, but in some embodiments the treated area will include only texturing patterns or only barriers. In one embodiment, the texturing patterns can include many different types of geometries based on device package characteristics and requirements.

In one embodiment, the treated areas can include the entire stiffener area or the aforementioned KIZ portion(s) that correspond to parts of the stiffener identified as prone to failure. The treatment can be performed by marking tools, including a laser marking tool. Among other advantages, the substrate surface treatment prior to attachment of the stiffener, such as the patterns, can clean the stiffener area and increase surface wettability and roughness that help to improve the adhesive bonding of the stiffener to the substrate. The barrier 408a, 408b, 408c can function as a glue barrier to improve other failure modes, such as ineffective ECA filling. For example, the patterns and/or barriers can both aid in preventing excess bonding material, such as the ECA filling, from being deposited onto unwanted areas of the substrate surface.

As another example, in FIG. 4B, the treated areas can include other types of textures in other types of shapes, including a diamond pattern 408 in the curved shape of the stiffener area or smaller KIZ portions with different textures 410 and 412, that could be located underneath the tips of the curved shape of the stiffener, i.e., parts of the stiffener that have been identified as prone to failure.

With reference to FIGS. 4A-4B, the illustrated shapes and textures are by way of example only. In other embodiments, different shapes and different textures may be used to treat the substrate surface.

In one embodiment, the marking of the texture(s) and/or barrier(s) can take the form of etching that will change the profile of substrate surface. In one embodiment, the changed profile can be fully controllable in terms of pattern, e.g., 402, 404, 406, 408, 410 and 412, and/or depth of pattern. For ease of illustration, the example textures illustrated in FIGS. 4A-4B are regular patterns. However other patterns, including irregular patterns, can also be used, limited only by the capabilities of the marking tool used to treat the substrate surface.

In one embodiment, an ultraviolet laser tray marker, including either a focused OK (“FOK”) or legacy marker tool, can be used as the marker tool having the in-line process capability to meet the surface texturing and barrier requirements for treating a substrate surface for stiffener bonding.

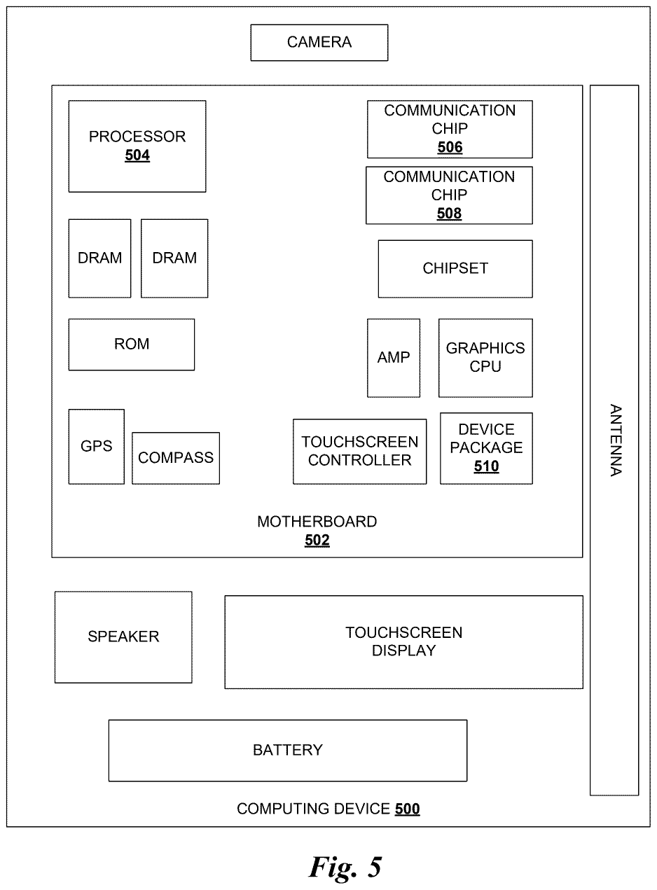

FIG. 5 is a schematic block diagram illustrating a computer system that utilizes a device package that may include an attachment, one or more dies, an adhesive fill layer, a solder mask, and a substrate, as described herein. FIG. 5 illustrates an example of computing device 500. Computing device 500 houses motherboard 502. Motherboard 502 may include a number of components, including but not limited to processor 504, device package 510, and at least one communication chip 506 and communication chip 508. Processor 504 is physically and electrically coupled to motherboard 502. For some embodiments, at least one communication chip 506 is also physically and electrically coupled to motherboard 502. For other embodiments, at least one communication chip 506 is part of processor 504.

Depending on its applications, computing device 500 may include other components that may or may not be physically and electrically coupled to motherboard 502. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

At least one communication chip 506 enables wireless communications for the transfer of data to and from computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. At least one communication chip 506 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

Processor 504 of computing device 500 includes an integrated circuit die packaged within processor 504. Device package 510 may be, but is not limited to, a packaging substrate and/or a printed circuit board. Device package 510 may include a substrate, dies, an attachment, an adhesive, a solder mask—or any other components from the FIGS. 1A-1C, 2A-2B, 3A-3B and 4A-4B described herein—of the computing device 500. Further, the device package 510 may implement retaining structures and/or pedestal structures on a die and a heat spreader.

Note that device package 510 may be a single component, a subset of components, and/or an entire system, as the materials, features, and components may be limited to device package 510 and/or any other component that requires materials, features, and components.

For some embodiments, the integrated circuit die may be packaged with one or more devices on device package 510 that include a thermally stable RFIC and antenna for use with wireless communications. The term “processor” may refer to any device or portion of a device that processes electronic data from registers and/or memory to transform that electronic data into other electronic data that may be stored in registers and/or memory.

At least one communication chip 506 also includes an integrated circuit die packaged within the communication chip 506. For some embodiments, the integrated circuit die of the communication chip may be packaged with one or more devices on the device package 510, as described herein.

The various features of the different embodiments described herein may be variously combined with some features included and others excluded to suit a variety of different applications. Various examples may be implemented using hardware elements, software elements, or a combination of both. In some examples, hardware elements may include devices, components, processors, microprocessors, circuits, circuit elements (e.g., transistors, resistors, capacitors, inductors, and so forth), integrated circuits, ASICs, PLDs, DSPs, FPGAs, memory units, logic gates, registers, semiconductor device, chips, microchips, chip sets, and so forth. In some examples, software elements may include software components, programs, applications, computer programs, application programs, system programs, machine programs, operating system software, middleware, firmware, software modules, routines, subroutines, functions, methods, procedures, software interfaces, APIs, instruction sets, computing code, computer code, code segments, computer code segments, words, values, symbols, or any combination thereof. Determining whether an example is implemented using hardware elements and/or software elements may vary in accordance with any number of factors, such as desired computational rate, power levels, heat tolerances, processing cycle budget, input data rates, output data rates, memory resources, data bus speeds and other design or performance constraints, as desired for a given implementation. It is noted that hardware, firmware and/or software elements may be collectively or individually referred to herein as “module,” or “logic.” A processor can be one or more combination of a hardware state machine, digital control logic, central processing unit, or any hardware, firmware and/or software elements.

Some examples may be implemented using or as an article of manufacture or at least one computer-readable medium. A computer-readable medium may include a non-transitory storage medium to store logic. In some examples, the non-transitory storage medium may include one or more types of computer-readable storage media capable of storing electronic data, including volatile memory or non-volatile memory, removable or non-removable memory, erasable or non-erasable memory, writeable or re-writeable memory, and so forth. In some examples, the logic may include various software elements, such as software components, programs, applications, computer programs, application programs, system programs, machine programs, operating system software, middleware, firmware, software modules, routines, subroutines, functions, methods, procedures, software interfaces, API, instruction sets, computing code, computer code, code segments, computer code segments, words, values, symbols, or any combination thereof.

According to some examples, a computer-readable medium may include a non-transitory storage medium to store or maintain instructions that when executed by a machine, computing device or system, cause the machine, computing device or system to perform methods and/or operations in accordance with the described examples. The instructions may include any suitable type of code, such as source code, compiled code, interpreted code, executable code, static code, dynamic code, and the like. The instructions may be implemented according to a predefined computer language, manner or syntax, for instructing a machine, computing device or system to perform a certain function. The instructions may be implemented using any suitable high-level, low-level, object-oriented, visual, compiled and/or interpreted programming language.

One or more aspects of at least one example may be implemented by representative instructions stored on at least one machine-readable medium which represents various logic within the processor, which when read by a machine, computing device or system causes the machine, computing device or system to fabricate logic to perform the techniques described herein. Such representations, known as “IP cores” may be stored on a tangible, machine readable medium and supplied to various customers or manufacturing facilities to load into the fabrication machines that actually make the logic or processor.

The appearances of the phrase “one example” or “an example” are not necessarily all referring to the same example or embodiment. Any aspect described herein can be combined with any other aspect or similar aspect described herein, regardless of whether the aspects are described with respect to the same figure or element. Division, omission or inclusion of block functions depicted in the accompanying figures does not infer that the hardware components, circuits, software and/or elements for implementing these functions would necessarily be divided, omitted, or included in embodiments.

Some examples may be described using the expression “coupled” and “connected” along with their derivatives. These terms are not necessarily intended as synonyms for each other. For example, descriptions using the terms “connected” and/or “coupled” may indicate that two or more elements are in direct physical or electrical contact with each other. The term “coupled,” however, may also mean that two or more elements are not in direct contact with each other, but yet still co-operate or interact with each other.

The terms “first,” “second,” and the like, herein do not denote any order, quantity, or importance, but rather are used to distinguish one element from another. The terms “a” and “an” herein do not denote a limitation of quantity, but rather denote the presence of at least one of the referenced items. The term “asserted” used herein with reference to a signal denote a state of the signal, in which the signal is active, and which can be achieved by applying any logic level either logic 0 or logic 1 to the signal. The terms “follow” or “after” can refer to immediately following or following after some other event or events. Other sequences of steps may also be performed according to alternative embodiments. Furthermore, additional steps may be added or removed depending on the particular applications. Any combination of changes can be used and one of ordinary skill in the art with the benefit of this disclosure would understand the many variations, modifications, and alternative embodiments thereof.

Disjunctive language such as the phrase “at least one of X, Y, or Z,” unless specifically stated otherwise, is otherwise understood within the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present. Additionally, conjunctive language such as the phrase “at least one of X, Y, and Z,” unless specifically stated otherwise, should also be understood to mean X, Y, Z, or any combination thereof, including “X, Y, and/or Z.”

Flow diagrams as illustrated herein provide examples of sequences of various process actions. The flow diagrams can indicate operations to be executed by a software or firmware routine, as well as physical operations. In some embodiments, a flow diagram can illustrate the state of a finite state machine (FSM), which can be implemented in hardware and/or software. Although shown in a particular sequence or order, unless otherwise specified, the order of the actions can be modified. Thus, the illustrated embodiments should be understood only as an example, and the process can be performed in a different order, and some actions can be performed in parallel. Additionally, one or more actions can be omitted in various embodiments; thus, not all actions are required in every embodiment. Other process flows are possible.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, and so forth.

Illustrative examples of the devices, systems, and methods disclosed herein are provided below. An embodiment of the devices, systems, and methods may include any one or more, and any combination of, the examples described below.

Example 1 is a method, system, apparatus or computer-readable medium in which an embodiment of a substrate surface treatment for stiffener bonding includes any of a device package, or a computing device having a processor and the device package, wherein the device package comprises a substrate, a stiffener having one or more parts prone to failure to bond with the substrate, a portion of a top surface of the substrate treated to change a profile of the portion, an adhesive material applied between a bottom surface of the stiffener and a stiffener area on the top surface of the substrate, and the stiffener bonded to the stiffener area on the substrate, the stiffener area encompassing the portion having the changed profile.

Example 2 is the method, system, apparatus or computer-readable medium as in Example 1, wherein the adhesive material comprising the device package is a liquid electrically conductive adhesive (ECA) material.

Example 3 is the method, system, apparatus or computer-readable medium as in any of Examples 1 and 2, wherein the portion of the top surface having the changed profile corresponds to a part of the stiffener that is prone to failure to bond with the substrate.

Example 4 is the method, system, apparatus or computer-readable medium as in any of Examples 1, 2 and 3, wherein the portion of the top surface of the substrate having the changed profile is a keep-in-zone (KIZ) portion, the changed profile to keep the adhesive material within the KIZ portion, and the adhesive material applied between the bottom surface of the stiffener and the KIZ portion to reduce a defect in the adhesive material causing the stiffener to fail to bond to the substrate.

Example 5 is the method, system, apparatus or computer-readable medium as in any of Examples 1, 2, 3 and 4, wherein the portion of the top surface of the substrate is the stiffener area on the top surface of the substrate.

Example 6 is the method, system, apparatus or computer-readable medium as in any of Examples 1, 2, 3, 4 and 5, wherein to change the profile of the portion of the top surface of the substrate, the substrate is treated with a marking tool, including a laser marking tool, capable of creating a texture to improve application of the adhesive material between the bottom surface of the stiffener and the stiffener area on the top surface of the substrate.

Example 7 is the method, system, apparatus or computer-readable medium as in any of Examples 1, 2, 3, 4, 5 and 6, wherein the texture includes any of a pattern and a barrier to improve surface wettability and effectiveness of adhesive material filling between the bottom surface of the stiffener and the stiffener area on the top surface of the substrate.

What is claimed is:

1. A device package, comprising:
a substrate;
a stiffener having one or more parts prone to failure to bond with the substrate;
a portion of a top surface of the substrate treated to change a profile of the portion;
an adhesive material applied between a bottom surface of the stiffener and a stiffener area on the top surface of the substrate; and
the stiffener bonded to the stiffener area on the substrate, the stiffener area encompassing the portion having the changed profile.

2. The device package of claim 1, wherein the adhesive material is a liquid electrically conductive adhesive (ECA) material.

3. The device package of claim 1, wherein the portion having the changed profile corresponds to a part of the stiffener prone to failure to bond with the substrate.

4. The device package of claim 3, wherein:
the portion of the top surface of the substrate having the changed profile is a keep-in-zone (KIZ) portion, the changed profile to keep the adhesive material within the KIZ portion; and
the adhesive material applied between the bottom surface of the stiffener and the KIZ portion to reduce a defect in the adhesive material causing the stiffener to fail to bond to the substrate.

5. The device package of claim 1, wherein the portion of the top surface of the substrate is the stiffener area on the top surface of the substrate.

6. The device package of claim 1, wherein to change the profile of the portion of the top surface of the substrate, the substrate is treated with a marking tool, including a laser marking tool, capable of creating a texture to improve application of the adhesive material between the bottom surface of the stiffener and the stiffener area on the top surface of the substrate.

7. The device package of claim 6, wherein the texture includes any of a pattern and a barrier to improve surface wettability and effectiveness of adhesive material filling between the bottom surface of the stiffener and the stiffener area on the top surface of the substrate.

8. A computing device, comprising:
a processor;
a device package, wherein the device package includes:
a substrate;
a stiffener having one or more parts prone to failure to bond with the substrate;
a portion of a top surface of the substrate treated to change a profile of the portion;
an adhesive material applied between a bottom surface of the stiffener and a stiffener area on the top surface of the substrate; and
the stiffener bonded to the stiffener area on the substrate, the stiffener area encompassing the portion having the changed profile.

9. The computing device of claim 8, wherein the adhesive material is a liquid electrically conductive adhesive (ECA) material.

10. The computing device of claim 8, wherein the portion having the changed profile corresponds to a part of the stiffener prone to failure to bond with the substrate.

11. The computing device of claim 10, wherein:
the portion of the top surface of the substrate having the changed profile is a keep-in-zone (KIZ) portion, the changed profile to keep the adhesive material within the KIZ portion; and
the adhesive material applied between the bottom surface of the stiffener and the KIZ portion to reduce a defect in the adhesive material causing the stiffener to fail to bond to the substrate.

12. The computing device of claim 8, wherein the portion of the top surface of the substrate is the stiffener area on the top surface of the substrate.

13. The computing device of claim 8, wherein to change the profile of the portion of the top surface of the substrate, the substrate is treated with a marking tool, including a laser marking tool, capable of creating a texture to improve application of the adhesive material between the bottom surface of the stiffener and the stiffener area on the top surface of the substrate.

14. The computing device of claim 13, wherein the texture includes any of a pattern and a barrier to improve surface wettability and effectiveness of adhesive material filling between the bottom surface of the stiffener and the stiffener area on the top surface of the substrate.
